(19) United States
(12) Patent Application Publication
(10) Pub. No.: US 2012/0120080 A1
(43) Pub. Date: May 17, 2012

(54) LIGHT GUIDE WITH DIFFUSIVE LIGHT INPUT INTERFACE

(75) Inventors: Lai Wang, Milpitas, CA (US); Douglas Carl Burstedt, San Diego, CA (US); Kollengode S. Narayanan, Cupertino, CA (US); Kebin Li, Fremont, CA (US); Ion Bita, San Jose, CA (US); Marek Mienko, San Jose, CA (US); Russell Wayne Gruhlke, Milpitas, CA (US)

(73) Assignee: QUALCOMM MEMS Technologies, Inc., San Diego, CA (US)

(21) Appl. No.: 13/278,411

(22) Filed: Oct. 21, 2011

Related U.S. Application Data
(60) Provisional application No. 61/414,345, filed on Nov. 16, 2010.
(60) Provisional application No. 61/452,969, filed on Mar. 15, 2011.

(51) Int. Cl. G06F 13/14; H05K 13/00; F21V 8/00

(52) U.S. Cl. 345/520; 362/608; 362/602; 29/592.1

(57) ABSTRACT

This disclosure provides systems, methods and apparatus for providing illumination by using a light guide to distribute light. In one aspect, the light guide has a surface, such as an edge, into which light is injected. The surface is treated to create a diffusive interface with a light source. For example, the surface may be subjected to abrasion to form a frosted surface that acts as the diffusive interface, or a diffusive structure may be attached to the edge, with the attached diffusive structure functioning as the diffusive interface. The diffusive interface diffuses light entering into the light guide, and can thereby increase the uniformity of light propagating within the light guide. The light guide may be provided with light turning features that redirect light out of the light guide. In some implementations, the redirected light may be applied to illuminate a display.

### REFERENCE TO RELATED APPLICATION

This application claims the priority benefit under 35 U.S.C. §119(e) of U.S. provisional Application No. 61/452,969, filed Mar. 15, 2011, entitled “LIGHT GUIDE WITH DIFFUSIVE LIGHT INPUT INTERFACE,” and U.S. provisional Application No. 61/414,345, filed Nov. 16, 2010, entitled “LIGHT GUIDE WITH DIFFUSIVE LIGHT INPUT INTERFACE,” both of which are assigned to the assignee hereof. The disclosures of the prior applications are considered part of, and are incorporated by reference in their entireties, in this disclosure.

### TECHNICAL FIELD

This disclosure relates to illumination devices, including illumination devices for displays, particularly illumination devices having light guides, and to electromechanical systems.

### DESCRIPTION OF THE RELATED TECHNOLOGY

Electromechanical systems include devices having electrical and mechanical elements, actuators, transducers, sensors, optical components (e.g., minors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a metallic membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

Reflected ambient light is used to form images in some display devices, such as those using pixels formed by interferometric modulators. The perceived brightness of these displays depends upon the amount of light that is reflected towards a viewer. In low ambient light conditions, light from an artificial light source is used to illuminate the reflective pixels, which then reflect the light towards a viewer to generate an image. To meet market demands and design criteria, new illumination devices are continually being developed to meet the needs of display devices, including reflective and transmissive displays.

### SUMMARY

The systems, methods and devices of the disclosure each have several innovative aspects, no single one of which is solely responsible for the desirable attributes disclosed herein.

One innovative aspect of the subject matter described in this disclosure can be implemented in an illumination system. The illumination system includes a light guide having a frosted light input surface. A light source is configured to direct light into the frosted surface for light input. The frosted surface can have a surface roughness Ra of about 0.01−10 μm, about 0.1-5 μm, about 0.2-2 μm, about 0.7-2 μm, or about 0.8-1.2 μm in some implementations. In some implementations, the frosted light input surface is on an edge of the light guide. Peaks and valleys of material on the frosted light input surface may define striations extending along a short dimension of the edge. The striations may be non-uniform and irregularly spaced apart.

Another innovative aspect of the subject matter described in this disclosure can be implemented in a method for manufacturing an illumination system. The method includes providing a light guide having a frosted surface for light input; and providing a light source attached to the light guide and configured to direct light into the frosted surface. Roughening the surface can include grinding the surface in some implementations or sanding the surface in some other implementations, for example with a sanding implement having a grit number of about 220 or more. The grinding or sanding may be performed by moving abrasive agents against an edge of the light in a direction substantially along a short dimension of the edge. The resulting surface can have a surface roughness Ra of about 0.01-10 μm, about 0.1-5 μm, about 0.2-2 μm, about 0.7-2 μm, or about 0.8-1.2 μm in some implementations. The roughening may form striations that extend along the short dimension of the edge.

Yet another innovative aspect of the subject matter described in this disclosure can be implemented in an illumination system. The illumination system includes a light guide having a light input surface. A diffuser is coupled to the light input surface. A light source is configured to direct light into the light guide through the diffuser. The diffuser can be a layer attached to or deposited on the surface for light input in some implementations. In some other implementations, the diffuser can be a structure have embedded particles for diffusing light or a surface treated to diffuse light. In some implementations, the treated surface can be a frosted surface.

Another innovative aspect of the subject matter described in this disclosure can be implemented in a method for manufacturing an illumination system. The method includes providing a light guide having a light input surface. A diffuser is coupled to the surface for light input. A light source is attached to the light guide and configured to direct light into the light guide through the diffuser.

Another innovative aspect of the subject matter described in this disclosure can be implemented in an illumination system. The illumination system includes a light guide having a light input interface; a light source configured to inject light into the light guide via the light input interface; and a means for diffusing incoming light at the light input interface. In some implementations, the means for diffusing incoming light at the light input interface may be a frosted surface of the light input interface. In some other implementations, the means for diffusing light may be a coating applied to the light input edge or an optically diffusive structure attached to the light input edge. In some implementations, the optically diffusive structure may have a frosted light input surface disposed between the light source and the light input edge or may have a plurality of embedded particles for diffusing light.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 8A-8E show examples of cross-sectional schematic illustrations of various stages in a method of making an interferometric modulator.

FIG. 9 shows an example of a photograph showing a top-down view of a light guide in which the cross-hatch effect is present.

FIG. 10 shows an example of a cross-section of an illumination system with a light diffusing light guide surface.

FIG. 11 shows an example of a cross-section of an illumination system with an attached light diffusing structure.

FIG. 12 shows another example of a cross-section of an illumination system with an attached light diffusing structure.

FIG. 13A shows an example of a cross-section of an illumination device with light sources embedded in a light diffusing structure.

FIG. 13B shows an example of a cross-section of an illumination device with light sources disposed on a major, flat surface of a light diffusing structure.

FIG. 14A shows an example of a cross-section of the illumination system of FIG. 10 provided with a display device.

FIG. 14B shows an example of a cross-section of the illumination system of FIG. 11 provided with a display device.

FIG. 14C shows an example of a cross-section of the illumination system of FIG. 12 provided with a display device.

FIG. 15A shows a photograph of an example of a top view of an illuminated light guide without a light diffusing structure or frosted surface.

FIG. 15B shows a photograph of an example of a top view of an illuminated light guide having an attached light diffusing structure.

FIG. 15C shows a photograph of an example of a top view of an illuminated light guide having a frosted light input surface.

FIG. 16A is a photograph showing an example of a top view of a light guide configuration used to derive the graph shown in FIG. 16B.

FIG. 16B is a graph showing the average brightness along the center line of the light guide of FIG. 16A.

FIG. 17 is a block diagram depicting an example of a method of manufacturing an illumination system.

FIG. 18A shows an example of abrasive movement substantially in the “vertical” direction, along the short dimension of the light input surface.

FIG. 18B shows an example of abrasive movement substantially in the “parallel” direction. along the long dimension of the light input surface.

FIG. 19 shows a graph of the surface topology of an example of a surface roughened with sand paper, with the sand paper moved in the direction of the short dimension.

FIG. 20 is a block diagram depicting another example of a method of manufacturing an illumination system.

FIGS. 21A and 21B show examples of system block diagrams illustrating a display device that includes a plurality of interferometric modulators.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. The described implementations may be implemented in any device that is configured to display an image, whether in motion (e.g., video) or stationary (e.g., still image), and whether textual, graphical or pictorial. More particularly, it is contemplated that the implementations may be implemented in or associated with a variety of electronic devices such as, but not limited to, mobile telephones, multimedia Internet enabled cellular telephones, mobile television receivers, wireless devices, smartphones, bluetooth devices, personal data assistants (PDAs), wireless electronic mail receivers, hand-held or portable computers, netbooks, notebooks, smartbooks, printers, copiers, scanners, facsimile devices, GPS receivers/navigators, cameras, MP3 players, camcorders, game consoles, wrist watches, clocks, calculators, television monitors, flat panel displays, electronic reading devices (e.g., e-readers), computer monitors, auto displays (e.g., odometer display, etc.), cockpit controls and/or displays, camera view displays (e.g., display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, packaging (e.g., MEMS and non-MEMS), aesthetic structures (e.g., display of images on a piece of jewelry) and a variety of electromechanical systems devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes, electronic test equipment. Thus, the teachings are not intended to be limited to the implementations depicted solely in the Figures, but instead have wide applicability as will be readily apparent to one having ordinary skill in the art.

In some implementations, an illumination system is provided with a light guide to distribute light. In one aspect, the light guide has a surface into which light from a light source is injected. The surface is treated to create a diffusive light receiving interface. For example, the surface may be subjected to abrasion to form a rough surface that acts as the diffusive interface, or a diffuser may be attached to the surface, with the attached diffuser functioning as the diffusive interface with the light source. In some implementations, the treated surface is an edge of the light guide. The edge may be roughened by abrasion proceeding in a direction that is roughly parallel to the short or width dimension of the edge, thereby forming striations extending along that short dimension of the edge. The roughened surface may have a surface roughness Ra of about 0.01-10 μm, about 0.1-5 μm, about 0.2-2 μm, about 0.7-2 μm, or about 0.8-1.2 μm in some implementations. The light guide can be provided with light turning features that redirect light out of the light guide. In some implementations, the redirected light can be applied to illuminate a display.

Particular implementations of the subject matter described in this disclosure can be implemented to realize one or more of the following potential advantages. The diffuser diffuses light entering the light guide, thereby increasing the uniformity of the intensity of the light propagating within the light guide. The diffusion may reduce or eliminate the cross-hatching effect common to light emitted from some light source arrangements, such as spaced-apart arrays of discrete light sources. In addition, the greater light uniformity within the light guide can increase the uniformity of the intensity of light ejected from the light guide and used to illuminate an object, such as a display. Thus, highly uniform illumination of a display may be achieved in some implementations.

One example of a suitable MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity, i.e., by changing the position of the reflector.

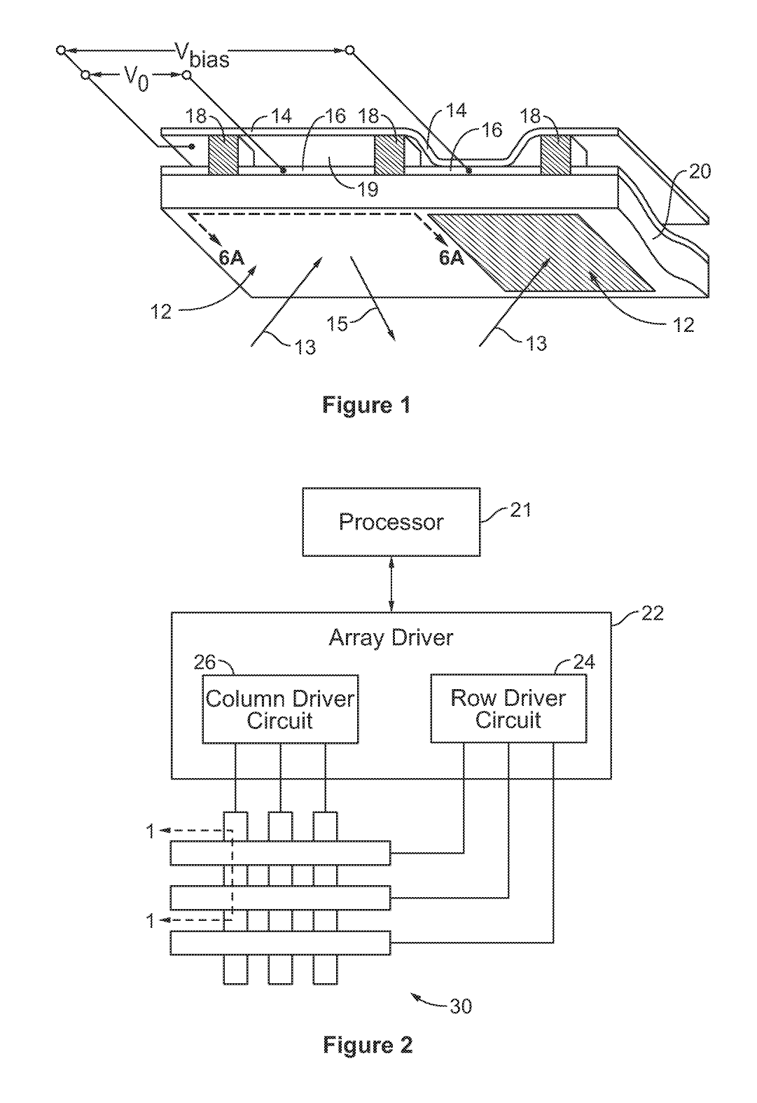

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when actuated, reflecting light outside of the visible range (e.g., infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows 13 indicating light incident upon the pixels 12, and light 15 reflecting from the pixel 12 on the left. Although not illustrated in detail, it will be understood by one having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the pixel 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, e.g., chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be on the order of 1-1000 um, while the gap 19 may be on the order of <10,000 Angstroms (Å).

In some implementations, each pixel of the IMOD, whether in the actuated or relaxed state, is essentially a capacitor formed by the fixed and moving reflective layers. When no voltage is applied, the movable reflective layer 14a remains in a mechanically relaxed state, as illustrated by the pixel 12 on the left in FIG. 1, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated pixel 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, e.g., a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

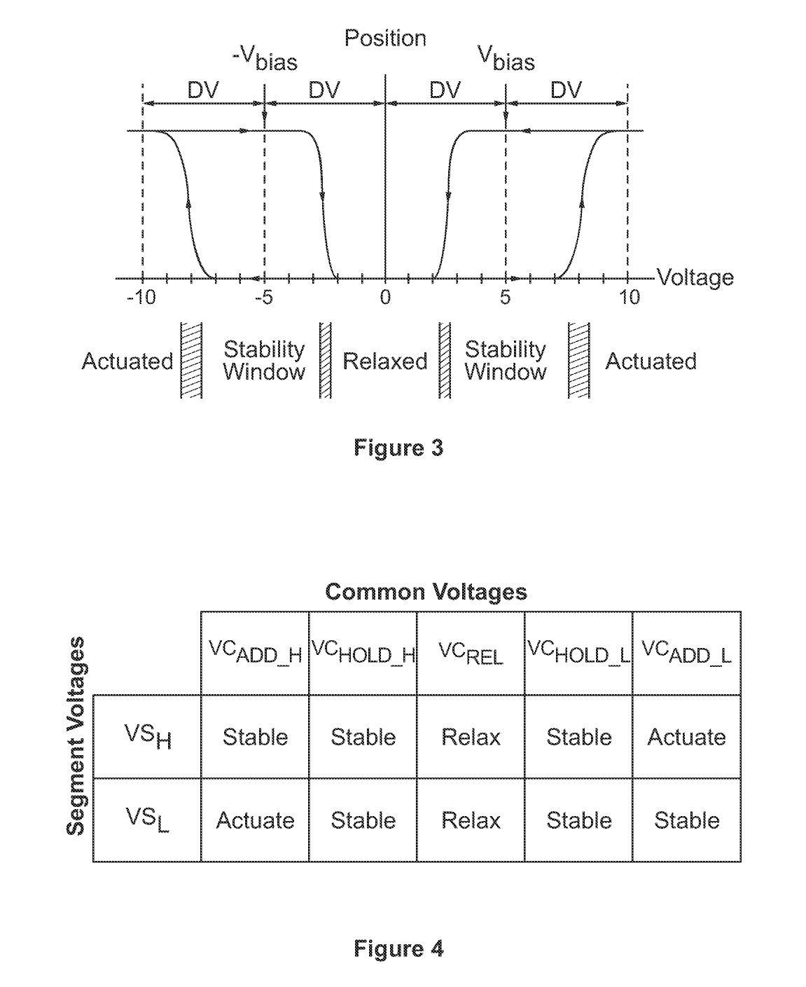

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may require, for example, about a 10-volt potential difference to cause the movable reflective layer, or minor, to change from the relaxed state to the actuated state. When the voltage is reduced from that value, the movable reflective layer maintains its state as the voltage drops back below, e.g., 10-volts, however, the movable reflective layer does not relax completely until the voltage drops below 2-volts. Thus, a range of voltage, approximately 3 to 7-volts, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about 10-volts, and pixels that are to be relaxed are exposed to a voltage difference of near zero volts. After addressing, the pixels are exposed to a steady state or bias voltage difference of approximately 5-volts such that they remain in the previous strobing state. In this example, after being addressed, each pixel sees a potential difference within the “stability window” of about 3-7-volts. This hysteresis property feature enables the pixel design, e.g., illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

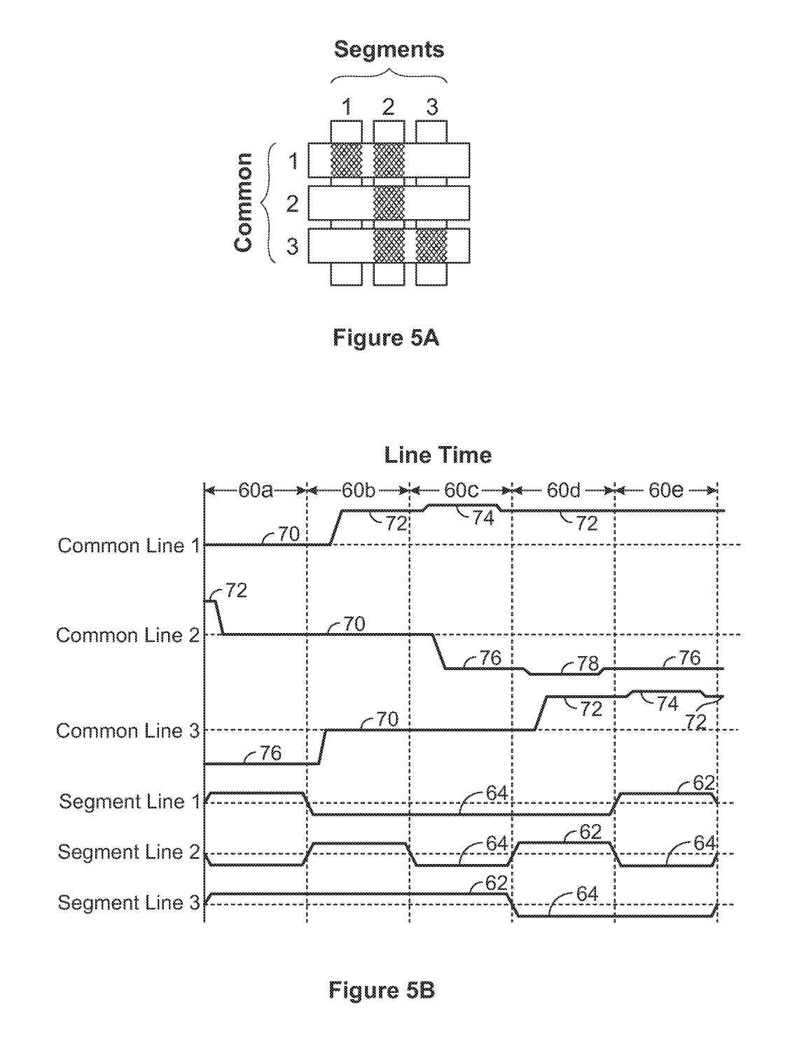

As illustrated in FIG. 4 (as well as in the timing diagram shown in FIG. 5B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator (alternatively referred to as a pixel voltage) is within the relaxation window (see FIG. 3, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD H} or a low hold voltage VC_{HOLD L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, i.e., the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which always produce the same polarity potential difference across the modulators. In some other implementations, signals can be used which alternate the polarity of the potential difference of the modulators. Alternation of the polarity across the modulators (that is, alternation of the polarity of write procedures) may reduce or inhibit charge accumulation which could occur after repeated write operations of a single polarity.

FIG. 5A shows an example of a diagram illustrating a frame of display data in the 3×3 interferometric modulator display of FIG. 2. FIG. 5B shows an example of a timing diagram for common and segment signals that may be used to write the frame of display data illustrated in FIG. 5A. The signals can be applied to the, e.g., 3×3 array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, e.g., a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a: a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}-relax and VC_{HOLD L}-stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the necessary line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

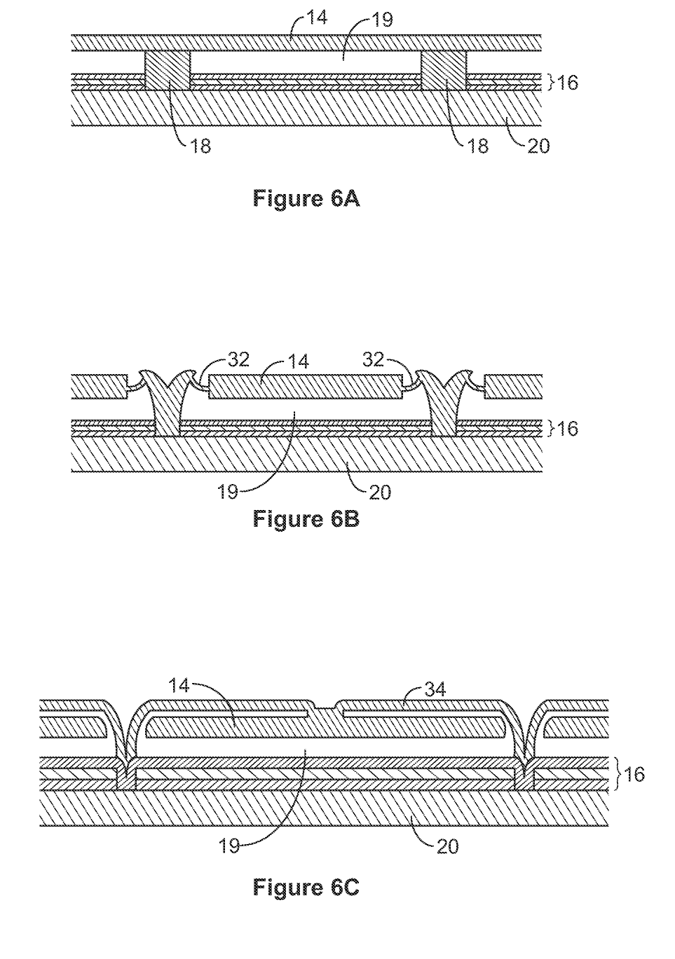

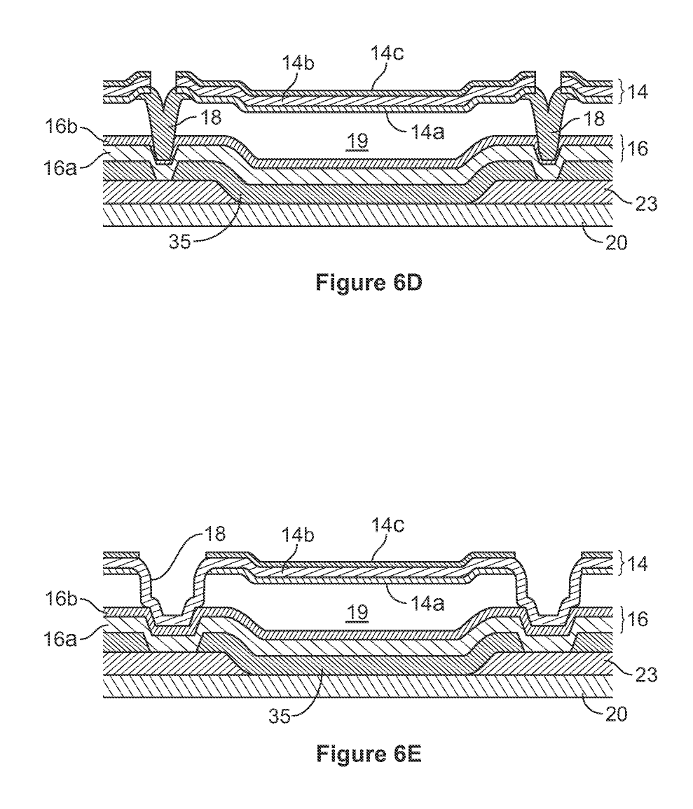

The details of the structure of interferometric modulators that operate in accordance with the principles set forth above may vary widely. For example, FIGS. 6A-6E show examples of cross-sections of varying implementations of interferometric modulators, including the movable reflective layer 14 and its supporting structures. FIG. 6A shows an example of a partial cross-section of the interferometric modulator display of FIG. 1, where a strip of metal material, i.e., the movable reflective layer 14 is deposited on supports 18 extending orthogonally from the substrate 20. In FIG. 6B, the movable reflective layer 14 of each IMOD is generally square or rectangular in shape and attached to supports at or near the corners, on tethers 32. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, e.g., an Al alloy with about 0.5% Cu, or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (e.g., between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, a SiO₂layer, and an aluminum alloy that serves as a reflector and a bussing layer, with a thickness in the range of about 30-80 Ø, 500-1000 Ø, and 500-6000 Ø, respectively. The one or more layers can be patterned using a variety of techniques, including photolithography and dry etching, including, for example, CF₄ and/or O₂ for the MoCr and SiO₂ layers and Cl₂ and/or BCl₃ for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 6E shows another example of an IMOD, where the movable reflective layer 14 is self supporting. In contrast with FIG. 6D, the implementation of FIG. 6E does not include support posts 18. Instead, the movable reflective layer 14 contacts the underlying optical stack 16 at multiple locations, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer.

In implementations such as those shown in FIGS. 6A-6E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 6A-6E can simplify processing, such as, e.g., patterning.

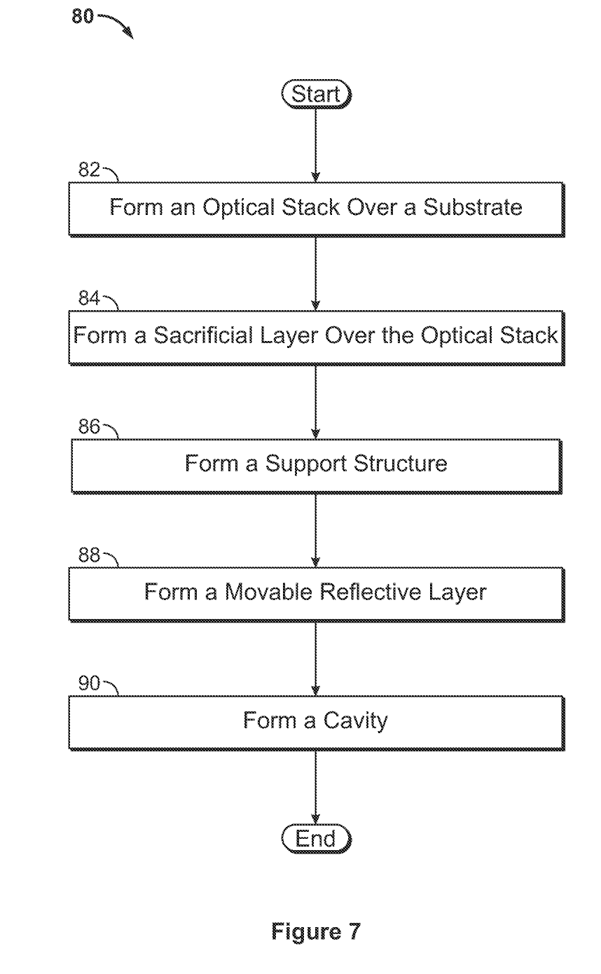

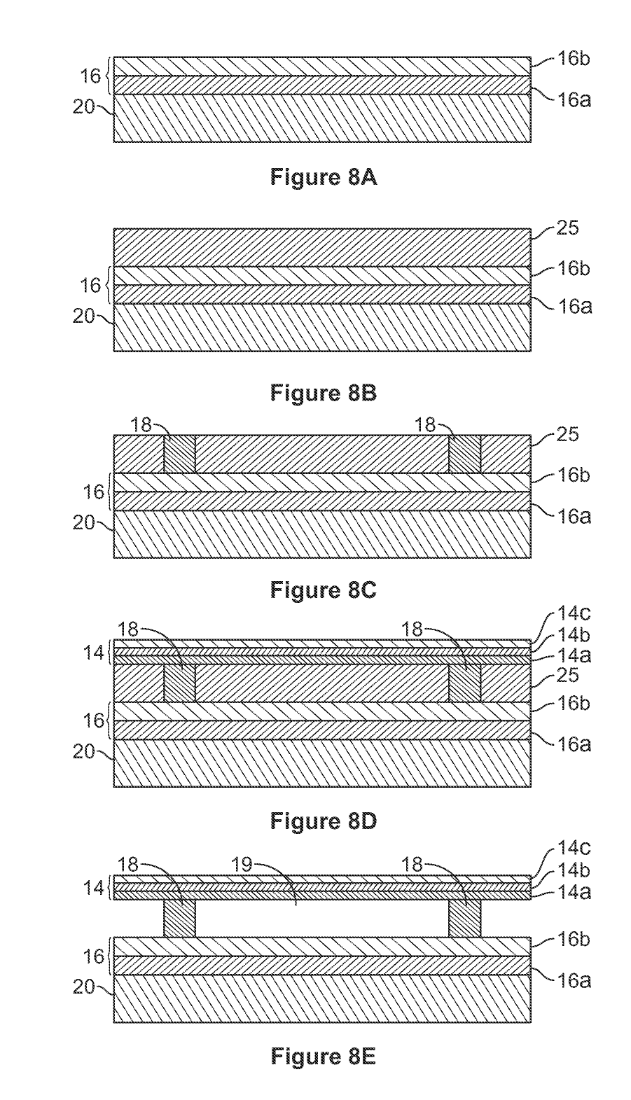

FIG. 7 shows an example of a flow diagram illustrating a manufacturing process 80 for an interferometric modulator, and FIGS. 8A-8E show examples of cross-sectional schematic illustrations of corresponding stages of such a manufacturing process 80. In some implementations, the manufacturing process 80 can be implemented to manufacture, e.g., interferometric modulators of the general type illustrated in FIGS. 1 and 6, in addition to other blocks not shown in FIG. 7. With reference to FIGS. 1, 6 and 7, the process 80 begins at block 82 with the formation of the optical stack 16 over the substrate 20. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, e.g., cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display.

The process 80 continues at block 84 with the formation of a sacrificial layer 25 over the optical stack 16. The sacrificial layer 25 is later removed (e.g., at block 90) to form the cavity 19 and thus the sacrificial layer 25 is not shown in the resulting interferometric modulators 12 illustrated in FIG. 1. FIG. 8B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (Si), in a thickness selected to provide, after subsequent removal, a gap or cavity 19 (see also FIGS. 1 and 8E) having a desired design size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

The process 80 continues at block 86 with the formation of a support structure e.g., a post 18 as illustrated in FIGS. 1, 6 and 8C. The formation of the post 18 may include patterning the sacrificial layer 25 to form a support structure aperture, then depositing a material (e.g., a polymer or an inorganic material, e.g., silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 6 and 8D. The movable reflective layer 14 may be formed by employing one or more deposition steps, e.g., reflective layer (e.g., aluminum, aluminum alloy) deposition, along with one or more patterning, masking, and/or etching steps. The movable reflective layer 14 can be electrically conductive, and referred to as an electrically conductive layer. In some implementations, the movable reflective layer 14 may include a plurality of sub-layers 14a, 14b, 14c as shown in FIG. 8D. In some implementations, one or more of the sub-layers, such as sub-layers 14a, 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 may also be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, e.g., cavity 19 as illustrated in FIGS. 1, 6 and 8E. The cavity 19 may be formed by exposing the sacrificial material 25 (deposited at block 84) to an etchant. For example, an etchable sacrificial material such as Mo or amorphous Si may be removed by dry chemical etching, e.g., by exposing the sacrificial layer 25 to a gaseous or vaporous etchant, such as vapors derived from solid XeF₂ for a period of time that is effective to remove the desired amount of material, typically selectively removed relative to the structures surrounding the cavity 19. Other etching methods, e.g. wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

As described herein, the interferometric modulators 12 (FIG. 1) may function as reflective display elements and, in some implementations, may use ambient lighting or internal illumination, such as from a light source attached to the display, for their operation. In some of these implementations, an illumination source directs light into a light guide disposed forward of the display elements, from which light may thereafter be redirected to the display elements. The distribution of light within the light guide can determine the angular distribution or brightness uniformity of the display elements. If the light within the light guide is from a discrete light source and has a narrow directional intensity profile, it may produce dark regions within the light guide and consequently poor illumination of the display elements where the light guide is applied to illuminate a display illumination.

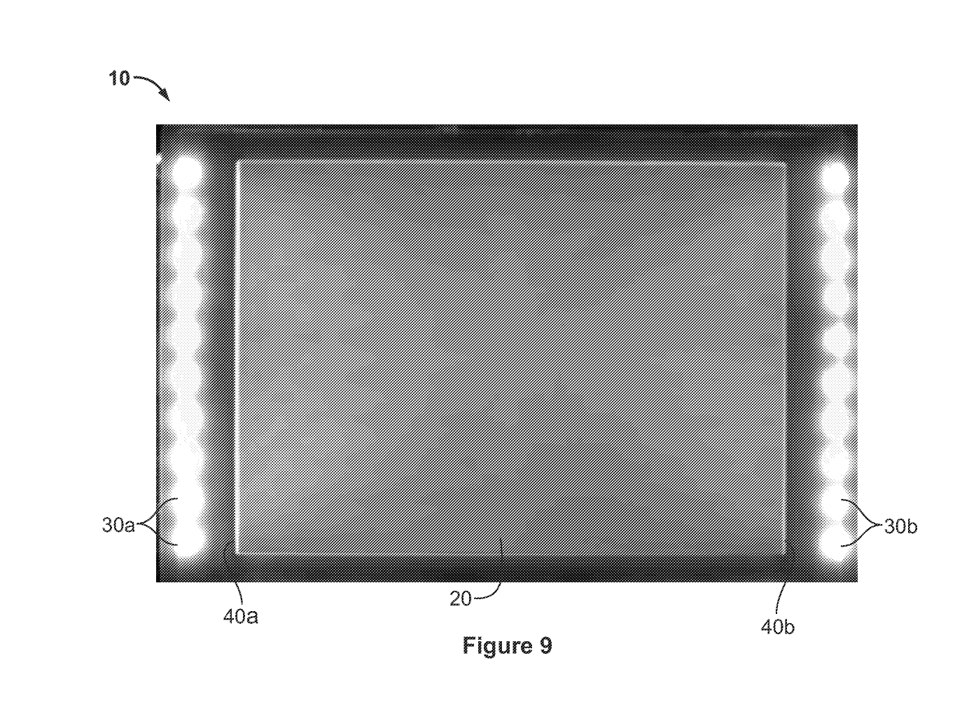

FIG. 9 shows an example of a photograph showing a top-down view of a light guide in which a cross-hatch effect is present. Two arrays of spaced-apart light sources 30a and 30b inject light into opposite sides of a light guide 20. Because the light sources 30a and 30b are spaced apart and also due to the refractive index difference between the light guide 20 and the air separating the light guide 20 from the light sources 30a and 30b, most of the light injected into the light guide 20 has a cone-shaped distribution. One of skill in the art will understand that the refractive index difference can limit the angular distribution of light injected into the light guide 20, since refraction at the air-light guide interface can change the direction of the injected light so that it propagates in directions closer to the normal to the light sources, and since this difference can cause light incident on a side of the light guide 20 at small angles (relative to that side) to be reflected off that side, rather than propagate into the light guide 20. Consequently, a large portion of the light entering the light guide may be roughly normal to light sources 30a and 30b and relatively little light is injected into the regions of the light guide 20 directly between the light sources 30a and 30b. As a result, a cross-hatch effect, with alternating regions of high and low brightness is observed in the light guide 20. After entering the light guide 20, light may naturally diffuse with distance from the light sources 30a and 30b. As a result, the cross-hatch effect is most pronounced in regions directly adjacent the light sources 30a and 30b and causes poor brightness uniformity and an objectionable appearance within those regions as seen in FIG. 9.

In some implementations, the cross-hatch effect is reduced or eliminated by treating the light input surface of the light guide to provide a light diffusing interface. The light input surface may be disposed on top or bottom surfaces of the light guide. In some other implementations, for example as illustrated in FIG. 9, the light input surface is disposed at an edge of the light guide. Treating the light input surface may involve changing the physical structure or topology of the light input surface itself, e.g., roughening the surface, and/or adding an additional structure to that surface, including a light diffusive coating and an adhered light diffusing structure. The adhered diffusive structure may be, for example a layer of material, or a more substantial structure, as described herein.

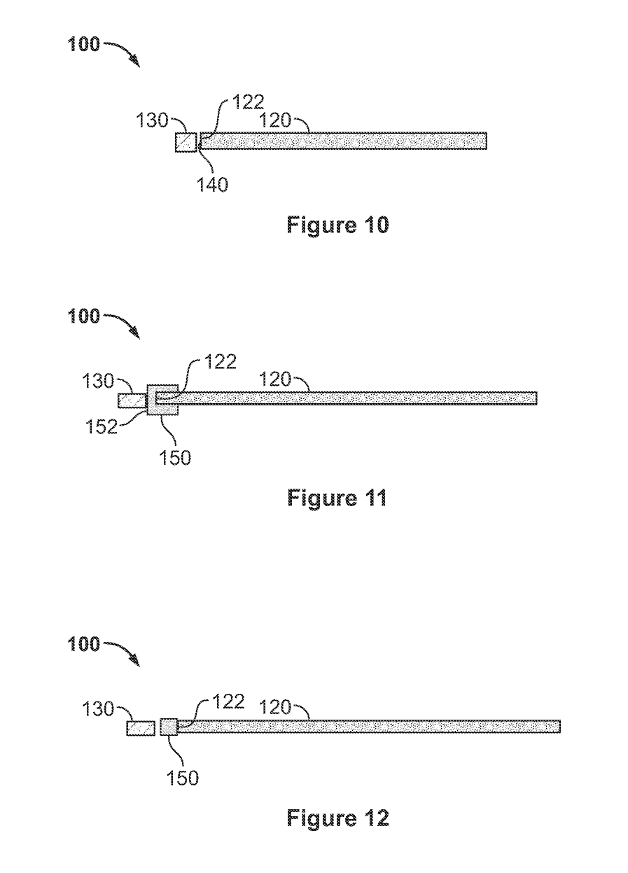

FIG. 10 shows an example of a cross-section of an illumination system 100 with a light diffusive light guide surface. A light guide 120 has a light input surface 122 disposed at an edge of the light guide 120. A light source 130 is configured to direct light into the light guide 120. The light input surface 122 has been treated to form a light diffusing surface, e.g., a rough surface.

With continued reference to FIG. 10, the light guide 120 can be formed of one or more layers of material. Examples of materials include the following: acrylics, acrylate copolymers, UV-curable resins, polycarbonates, cycloolefin polymers, polymers, organic materials, inorganic materials, silicates, alumina, sapphire, glasses, polyethylene terephthalate (“PET”), polyethylene terephthalate glycol (“PET-G”), silicon oxy-nitride, and/or other optically transparent materials.

The light source 130 may be a light emitting device such as, but not limited to, one or more light emitting diodes (LED), one or more incandescent bulbs, a light bar, one or more lasers, or any other form of light emitter. In some implementations, the light source 130 in one of a spaced-apart array of light emitters, such as the light sources 306 of FIG. 9. The light emitters may be disposed at one or more surfaces, e.g. multiple edges, of the light guide 120. In certain implementations, light from the light source 130 is injected into the light guide 120 such that a portion of the light propagates in a direction across at least a portion of the light guide 120 at a low-graze angle relative to the surface of the light guide 120 aligned with the display 160 such that the light is reflected within the light guide 120 by total internal reflection (“TIR”).

With continued reference to FIG. 10, the light input surface 122 has been treated to form the rough surface 140, which may also be referred to as a frosted surface. For example, the light input surface 122 may be subjected to abrasion or other processing to remove material from the light input surface 122, thereby forming the frosted surface 122. Thus, in this implementation, the light input surface 122 is the roughened surface. Examples of processes to abrade the light input surface 122 include grinding the surface (e.g., mechanically contacting the light input surface 122 with a grinding implement such as a grinding wheel or cylinder), rubbing the surface with sanding paper or other material with abrasive particles, projecting abrasive particles onto the light input surface, chemically etching the light input surface, and embossing or injection molding a rough surface onto the light input surface. In some implementations, the frosted light input surface is translucent and has a generally uniform appearance, as viewed by the naked eye.

In some implementations, sanding of the light input surface 122 can be accomplished using a sanding implement, e.g. sand paper, having a grit number of about 220 or more, about 280-1000, about 280-800, or about 400-600. In some applications, grit numbers of about 280-800, or about 400-600, provide particular advantages for reducing the cross-hatch effect while retaining high levels of brightness.

In some implementations, the reduction in brightness, relative to not having the frosted surface, is less than about 20%, or less than about 10%.

In some implementations, the frosted surface 140 has a surface roughness Ra of about 0.01-10 μm, about 0.1-5 μm, about 0.2-2 μm, about 0.7-2 μm, or about 0.8-1.2 μm. In some implementations, a surface roughness Ra of about 0.8-1.5 μm, or about 0.8-1.2 μm provides particular advantages for reducing the cross-hatch effect while providing an illumination device with good brightness levels. In some implementations, relative to not having the frosted surface present, the reduction in brightness is less than about 20%, or less than about 10%.

Roughness of a particular level may be achieved by forming a generally irregular distribution of peaks and valleys on a surface. In some implementations, the peaks and valleys defining roughness of a particular level can be generally arranged as irregularly spaced and sized striations that are elongated with a length (long) dimension extending roughly parallel to the short dimension of the edge 122, in implementations where the frosted surface 140 is disposed on the edge 122 of the light guide 120. As discussed herein, such striations may be formed by abrading the light input surface 140 with an abrasive implement moving roughly parallel to the short dimension of that surface 140. As also discussed herein, such striations have been found to provide a more uniform light distribution than striations with a length that extends parallel to the long dimension of the edge 122.

In some other implementations, rather than roughening the light input surface 122, or in addition to roughening the light input surface 122, a light diffusing structure may be applied to the light input surface 122. FIG. 11 shows an example of a cross-section of the illumination system 100 with an attached light diffusing structure 150. The light input surface 122 is disposed at an edge of the light guide 120. The diffusive structure 150 is attached to the light input surface 122 and the light source 130 is configured to inject light into the light guide 120 by directing the light through the diffusive structure 150 and then into the light input surface 122.

With continued reference to FIG. 11, the diffusive structure 150 may be a coating applied to the light input surface 122. For example, a coating may be deposited by vapor deposition, e.g. by a chemical vapor deposition or physical vapor deposition, onto the light input surface 122. The coating forms a rough surface, e.g., a surface having a surface roughness Ra of about 0.01-10 μm, about 0.1-5 μm, about 0.2-2 μm, or about 0.8-1.2 μm. Examples of suitable materials for the coating include porous materials and materials that form a rough texture as deposited.

In some other implementations, with continued reference to FIG. 11, the diffusive structure 150 may be a structure that is adhered to or otherwise attached to the light input surface 122. For example, the diffusive structure 150 may be a layer of light diffusive material that is adhered to the light input surface 122. For example, the diffusive structure 150 may be a layer of material that is attached to the light input surface 122 by a pressure sensitive adhesive. Examples of suitable layers of material that may be adhered to the light input surface include pressure sensitive adhesives, epoxies, and UV curable resins.

In some implementations, the diffusive structure 150 is more substantial than a layer. For example, the diffusive structure 150 may be a block or strip of material, such as a plastic or glass. Examples of suitable materials include acrylics, UV-curable resins, polycarbonates, polymers, terephthalate (“PET”), glasses and/or other optically transmissive materials.

The body of material forming the diffusive structure 150 may have a surface 152 that has been roughened so that the surface 152 functions as a diffusive surface. In some implementations, the roughness of the surface 152 may correspond to the surface roughness Ra of the surface 140 (FIG. 10) as described above and processes for roughening the surface 152 may be the same as that for the surface 140. For example, the peaks and valleys defining roughness of a particular level may be arranged as irregularly spaced and sized striations that are elongated with a length extending roughly parallel to the short dimension of the edge 122 of the light guide 120. Such striations may be formed by abrasion with an implement moving roughly parallel to that short dimension.

In some other implementations, the body of the diffusive structure 150 may be provided with micro-features that diffuse light. For example, the diffusive structure 150 may contain embedded particles that diffuse light propagating through the diffusive structure 150 to the light guide 120, or the surface of the diffusive structure 150 may contain micro-structures that refract and/or diffract light to diffuse light contacting those structures. In some implementations, the body of the diffusive structure 150 may contain light diffusing micro-features and the surface of the diffusive structure 150 may also be frosted or have a rough texture.

While shown for ease of illustration extending directly on the light input surface 122 and over and under the edge containing that surface 122, the diffusive structure 150 may be disposed on only the light input surface 122 in some implementations. FIG. 12 shows another example of a cross-section of an illumination system with attached light diffusing structure 150. As illustrated, the diffusive structure 150 may be dimensioned to contact only the light input surface 122.

Whether extending around the light input surface 122 as illustrated in FIG. 11, or contacting only the light input surface 122, in some implementations, the diffusive structure 150 has a haze number of about 65-85, about 70-80, or about 75-80. This haze number may be achieved by providing micro-features embedded in the body of the diffusive structure 150, by providing a rough surface on the diffusive structure 150, or a combination thereof. In some implementations where the diffusive structure has a rough surface 152, the surface 152 may have a surface roughness Ra of about 0.01-10 μm, about 0.1-5 μm, about 0.2-2 μm, about 0.7-2 μm, or about 0.8-1.2 μm, as described herein.

With reference to both FIGS. 11 and 12, the diffusive structure 150 may be attached to the light guide 120 by various means. For example, the diffusive structure 150 may simply be mechanically coupled to the light input surface 122 by placing the diffusive structure 150 directly adjacent that surface and using mechanical means (e.g., screws or devices that compress that the diffusive structure 150 against the light guide 120) to secure the diffusive structure to the light guide 120. In some implementations, the diffusive structure 150 is attached to the light guide 120 by an adhesive. The adhesive may be index-matched with the light guide, such that both the light guide and the adhesive have the same or similar refractive indices. The index matching can more closely couple the light outputted by the diffusive structure with the light guide 120, thereby reducing light loss relative to not being index matched and also allowing the diffuse light outputted by the diffusive structure to remain advantageously diffuse as it enters the light guide 120. Examples of adhesives include glues or epoxies, including optical cement, UV curable resins, super glues, and 5 minute epoxies. In some implementations, the refractive indices of the light guide 120, the adhesive, and the diffusive structure 150 differ by about 0.09 or less, about 0.07 or less, or about 0.05 or less. For example, the refractive index may be about 1.52 for a fused silica light guiding panel, about 1.49 for a PMMA diffusive structure and about 1.52 for an intervening adhesive (e.g., Sony SVR).

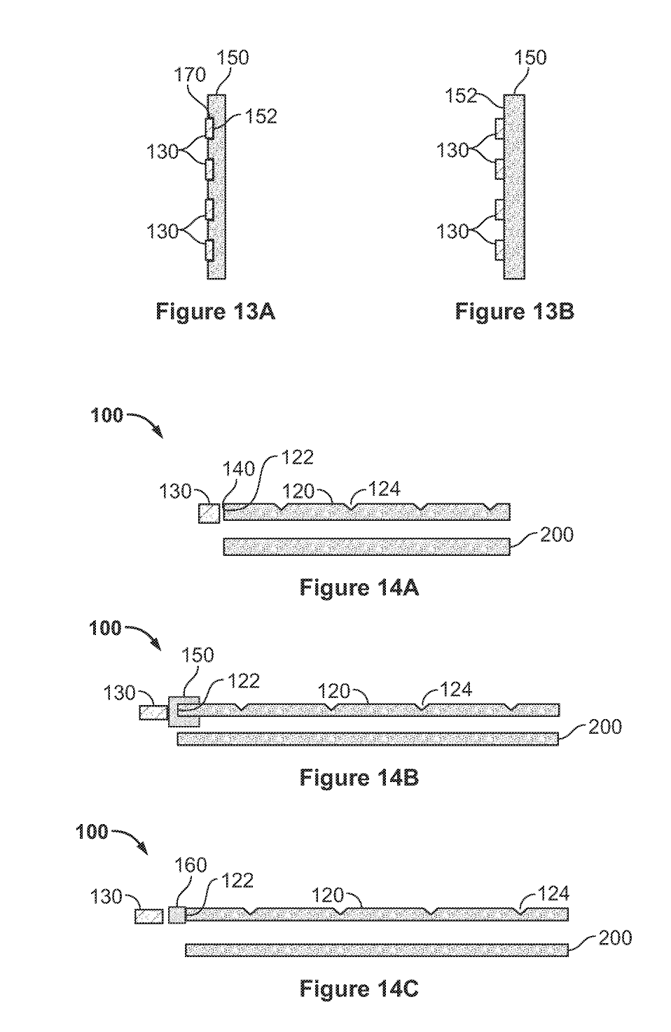

With reference to FIGS. 13A and 13B, the light source 130 may be situated on the diffusive structure 150 in various ways. FIG. 13A shows an example of a cross-section of an illumination device with light sources 130 embedded in the light diffusing structure 150. For example, the diffusive structure 150 may be provided with indentations 170 in which the light sources 130 are situated. FIG. 13B shows an example of a cross-section of an illumination device with light sources 130 disposed on a major, flat surface 152 of the light diffusing structure 150.

With reference to FIGS. 10-13B, various potential advantages may be achieved by utilizing the diffusive structures. For example, the light diffusing features of the diffusive structure 150 may be formed before or after attachment to the light guide 120. In some implementations, the light diffusing features of the diffusive structure 150 are formed before attachment to the light guide 120. For example, the diffusive structure 150 may be provided pre-fabricated with the desired roughness and/or diffusive features in the body of the diffusive structure 150. In some implementations, the diffusive structure 150 is subjected to an abrasion process to form a frosted surface 150 before attaching the diffusive structure 150 to the light guide 120. As a result, the light guide 120 may not be abraded or subjected to a coating process, and potential damage to the light guide 120 caused by such treatments can be avoided.

Also, separately forming and attaching the diffusive structure 150 to the light guide 120 allows freedom in the materials and processes used to form the diffusive structure 150. For example, the ability to use an adhesive layer to help index match the diffusive structure 150 to the light guide 120 can increase the number of materials which can be used for the diffusive structure 150. For example, the materials may be chosen for ease of manufacturing and compatibility with processes that form desired light diffusing structures such as diffusive micro-structures. In addition, processes that may be incompatible with the light guide 120, e.g., due to incompatibility with materials or concerns about low yields, may be applied to the separately-formed diffusive structure 150. For example, injection molding may be used to form the general shape of the diffusive structure 150 and/or diffusive micro-structures in the diffusive structure 150 where the light guide 120 is formed of a material, e.g., glass, for which injection molding is generally not applied. As a result, more complicated structures, including indentations 170 (FIG. 13A) to accommodate light sources 130, may be formed for the diffusive structure 150 than may be available if only the edge of the light guide 120 was processed. In addition, because the diffusive structure 150 is a relatively small piece of material and may be separate from other parts of the illumination system 100 during fabrication, it may be acceptable to apply relatively low yield fabrication processes to the diffusive structure 150, since the costs associated with making and discarding a defective diffusive structure 150 may be relatively low.

With reference to FIGS. 14A-14C, the illumination system may be applied to illuminate a display device 200. FIG. 14A shows an example of a cross-section of the illumination system of FIG. 10 provided with the display device 200. FIG. 14B shows an example of a cross-section of the illumination system of FIG. 11 provided with display device 200. FIG. 14C shows an example of a cross-section of the illumination system 100 of FIG. 12 provided with display device 200. In each of FIGS. 14A-14B, the light guide 120 may be provided with a plurality of light turning features 124. The light turning features 124 are configured to eject light, propagating within the light guide 120, out of the light guide 120 and towards the display 200. The light turning features 124 may be diffractive and/or reflective features, such as gratings, holograms, prismatic features, and/or reflective coatings, and may redirect the light out of the light guide 120 by diffraction and/or reflection.

In some implementations, the display device 200 is a reflective display and the light guide 120 functions as part of a front light. The display device 200 may include reflective pixels such as the pixels 12 illustrated in FIG. 1. Light ejected out of the light guide 120 is reflected by the display device 200 back through the light guide 120 towards a viewer on the same side of the display 200 as the light guide 120.

In some other implementations, the display device 200 is a transmissive display and the light guide 120 functions as part of a back light. The display device 200 may include transmissive pixels that allow light to propagate completely through the pixels. Light ejected out of the light guide 120 propagates through the reflective display 200 towards a viewer on a side of the display 200 opposite the light guide 120.

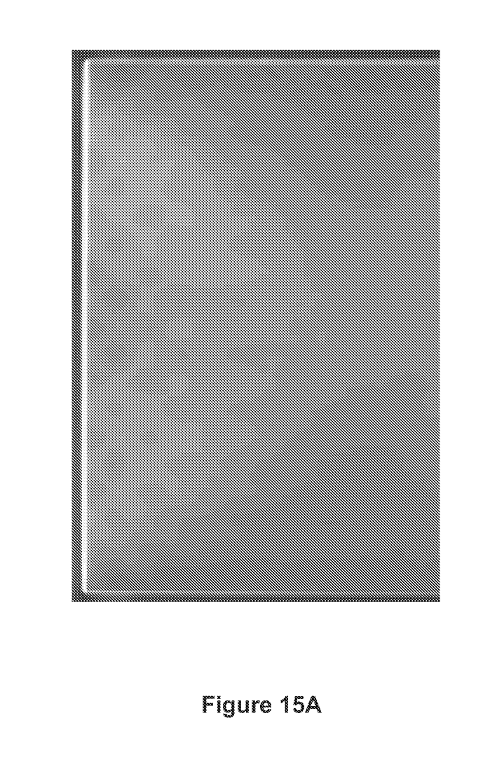

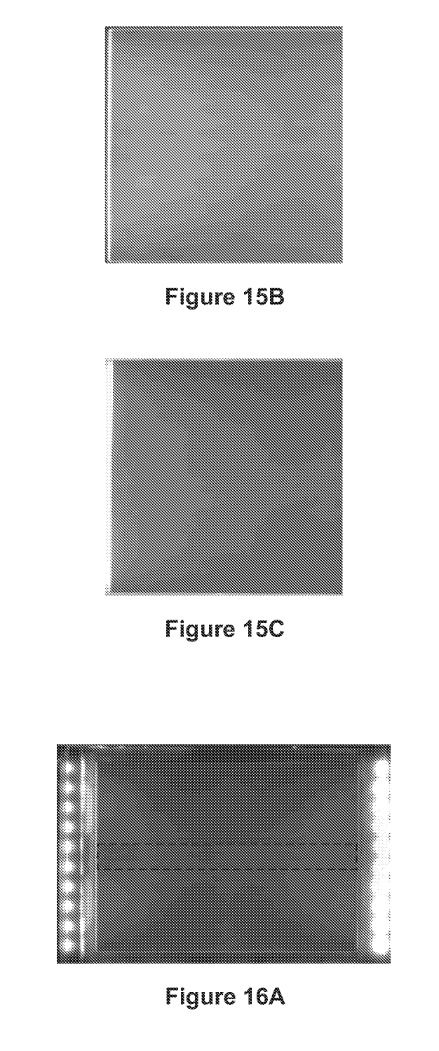

With reference to FIGS. 15A-15C, it can be seen that the diffusive structure 150 (FIGS. 11 and 12) and the frosted surface 140 (FIG. 10) are effective at mitigating the cross-hatching effect. FIG. 15A shows a photograph of an example of a top view of an illuminated light guide without a light diffusing structure or frosted surface for light input. Light is injected into the light guide from the left side by an array of spaced-apart of LED's (not shown). It can be seen that the injected light produces a cross-hatch effect which is particularly pronounced adjacent the left side of the light guide.

FIG. 15B shows a photograph of an example of a top view of an illuminated light guide having an attached light diffusing structure. In this example, the diffusive structure has a haze value of 79. Again, light is injected into the light guide from the left side by an array of spaced-apart of LED's (not shown). As can be expected, brightness decreases with distance from the light sources due, e.g., to light leakage from the light guide and/or light absorption. However, cross-hatching (the appearance of crossing, relatively high brightness regions separated by lower brightness regions) is diminished in comparison to FIG. 15A. Rather, a relatively gradual change in brightness across the light guide is achieved.

FIG. 15C shows a photograph of an example of a top view of an illuminated light guide having a frosted light input surface. The light input surface has been roughened by contact with an abrasive surface (using sanding paper with grit number 400) applied in a “vertical” direction, parallel with the thickness dimension of the light guide. Light is also injected into this light guide from the left side by an array of spaced-apart of LED's (not shown). No cross-hatching is observed, particularly in comparison to FIG. 15A. Rather, the brightness gradually decreases with distance from the light sources.

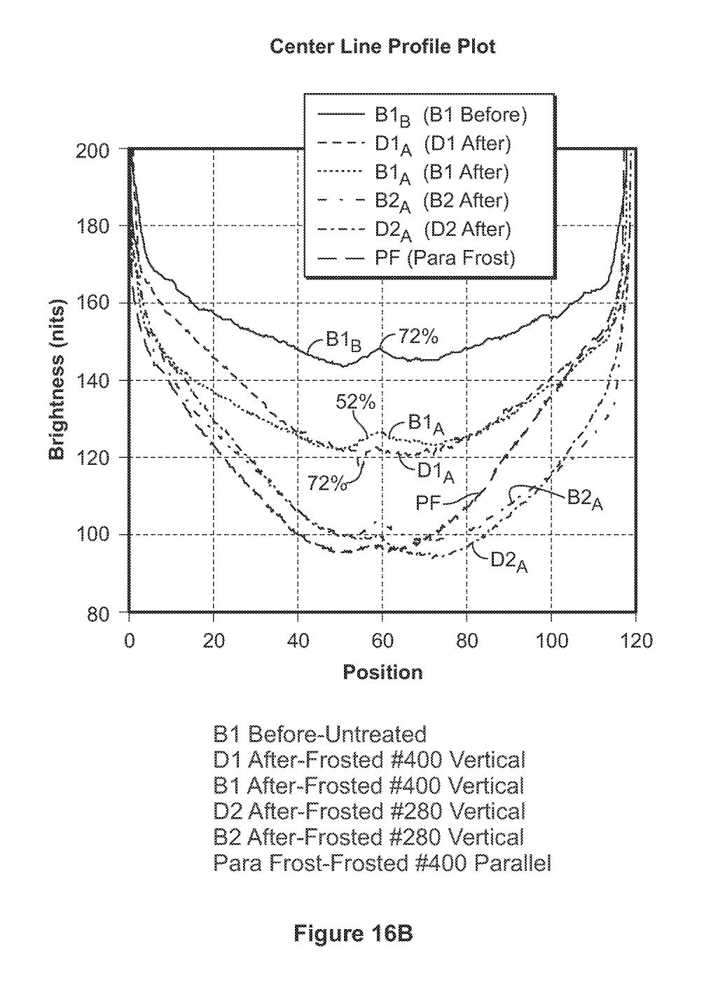

While reductions in brightness may occur when a light diffusing structure is applied to the light guide 120 (FIGS. 10-14C), these reductions may be mitigated in some implementations. FIG. 16A is a photograph showing an example of a top view of a light guide configuration used to derive the graph shown in FIG. 16B. FIG. 16B is a graph showing the average brightness along the center line of the light guide of FIG. 16A. The x-axis of FIG. 16B indicates arbitrary, equally spaced points between the left and right sides of the light guide of FIG. 16A. The y-axis indicates brightness at those points. The brightness is the average brightness at a particular distance from the left side, the average being taken along strips within the box indicated by the dotted lines of FIG. 16A.

With reference to FIG. 16B, light guides subjected to various treatments were tested. As a reference, an untreated light guide with a smooth, untreated light input edge was also tested. The untreated edge gave the greatest brightness, as shown by plot “B1_{B}” (B1 before). Other light input edges were subjected to roughening (sanding in the illustrated case). Plots “D1_{A}” (D1 after) and “B 1_{A}” (B1 after) show brightness after sanding the light input edge with grit #400 sand paper, with the direction of sanding being in the “vertical” direction, that is, the direction of the thickness of the light guide or the short dimension of the light guide edge. Plot “PF” (Para frost) shows brightness after sanding the light input edge with grit #400 sand paper, with the direction of sanding being in the “parallel” direction, that is, parallel to the long dimension of the light guide edge. Holding the grit number constant, it can be seen that the parallel sanding treatment decreased the brightness significantly, as the brightness decreased by over 20 nits at some points. Thus, it can be seen that applying a “vertical” abrasion treatment can provide the advantages of mitigating the cross-hatching effect, while maintaining high levels of brightness.

With continued reference to FIG. 16B, plots “D2_{A}” and “B2_{A}” show brightness after sanding the light input edge with grit #280 sand paper, with the direction of sanding being in the “vertical” direction. The brightness reduction was greater than observed for processing with grit #400 sand paper. Nevertheless, use of grit #280 was also found to be effective for reducing the cross-hatch effect.

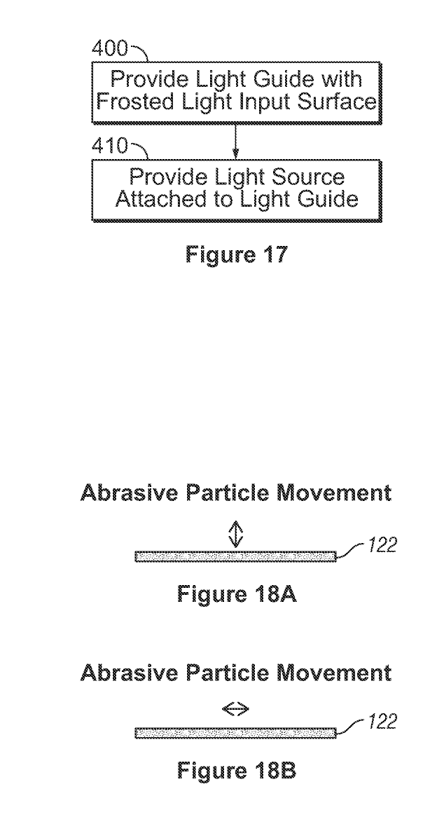

FIG. 17 is a block diagram depicting an example of a method of manufacturing an illumination system. A light guide with a frosted light input surface is provided 400. A light source is attached 410 to the light guide. The light source may be attached to the light guide by various methods, including chemically attaching the light source to the light guide (e.g., by adhesion) or mechanically attaching the light source using fasteners.

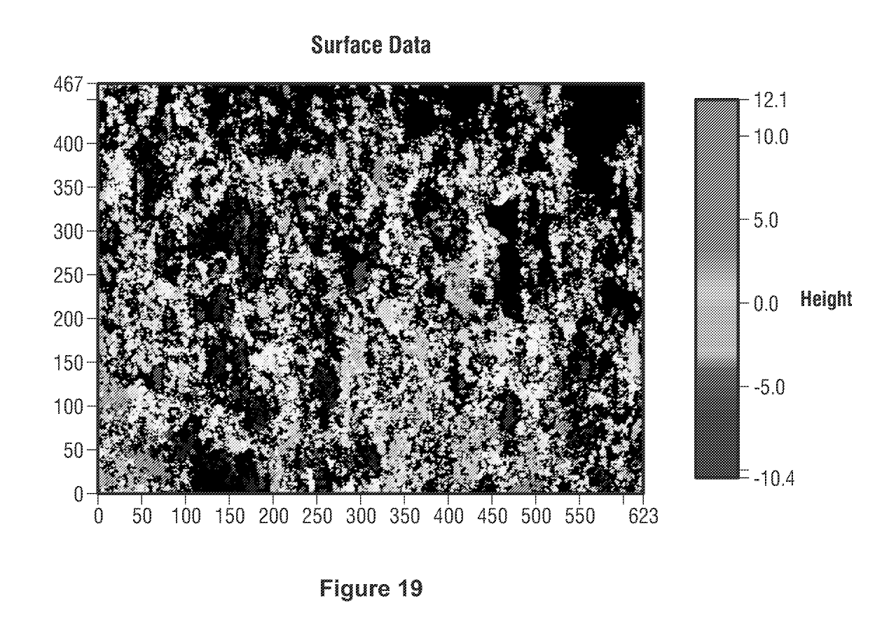

The frosted light input surface may be formed by various methods, including abrasion by contact with abrasive surfaces, such rough surfaces (e.g., rough surfaces that are harder than the light input surface) or surfaces having abrasive particles thereon, such as sand paper. The direction of movement of the abrasive surface may proceed in various directions. FIGS. 18A and 18B illustrate two such directions, with arrows indicating the direction of movement of an abrasive surface or particles relative to the light input surface 122. FIG. 18A shows an example of abrasive surface or particle movement substantially in the “vertical” direction, along the short dimension of the light input surface 122. FIG. 18B shows an example of abrasive surface or particle movement substantially in the “parallel” direction. along the long dimension of the light input surface 122. FIG. 19 shows a graph of the surface topology of an example of a surface roughened with an abrasive surface moved in the vertical direction (sand paper moved as illustrated in FIG. 18A). Valleys and peaks forming irregularly spaced and sized striations extending along the short dimension of the light guide edge can be seen. As noted herein, processing in the vertical direction has been found to provide the benefits of mitigating the cross-hatch effect while also lessening potential decreases in brightness. Without being limited by theory, it is believe that the short direction striations formed by “vertical” direction processing causes greater diffusion of light in the plane of the light guide than “parallel” direction processing, which is believed to cause relatively greater diffusion out of the plane of the light guide. As a result, parallel direction processing is believed to cause greater light loss out of the upper and lower major surfaces of the light guide, in comparison to vertical direction processing. In some other implementations, the direction of particle movement may be at an angle relative to the vertical or parallel directions or may follow a curve.

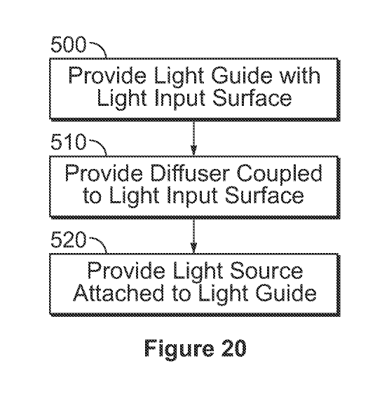

FIG. 20 is a block diagram depicting another example of a method of manufacturing an illumination system. A light guide with a light input surface is provided 500. A diffuser coupled to the light input surface is provided 510. A light source attached to the light guide is provided 520.

The diffuser may be various diffusers described herein, including a coating, layer, or more substantial physical structure. The diffuser is coupled to the light input surface by various methods, including chemical methods, such as adhesion, and mechanical methods. In some implementations, an index matching adhesive is used, as discussed herein. In some other implementations, the diffuser is a coating and is coupled to the light input surface by deposition on the light input surface, as described herein.

The light source may be attached to the light guide via attaching the light source to the diffuser coupled to the light input surface. The light source may be attached to the light source by various methods, as described herein, including chemical or mechanical attachment methods.

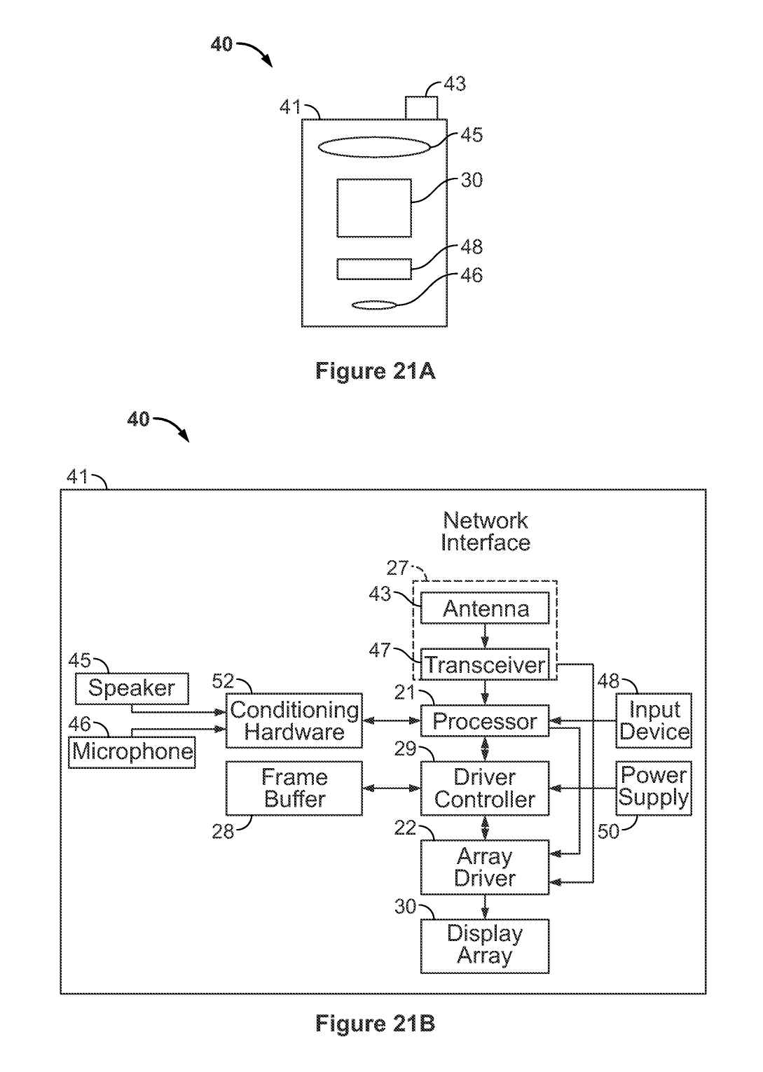

FIGS. 21A and 21B show examples of system block diagrams illustrating a display device 40 that includes a plurality of interferometric modulators. The display device 40 can be, for example, a cellular or mobile telephone. However, the same components of the display device 40 or slight variations thereof are also illustrative of various types of display devices such as televisions, e-readers and portable media players.

The display device 40 includes a housing 41, a display 30, an antenna 43, a speaker 45, an input device 48, and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber, and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 21B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. A power supply 50 can provide power to all components as required by the particular display device 40 design.

The network interface 27 includes the antenna 43 and the transceiver 47 so that the display device 40 can communicate with one or more devices over a network. The network interface 27 also may have some processing capabilities to relieve, e.g., data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g or n. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation, and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (e.g., an IMOD controller). Additionally, the array driver 22 can be a conventional driver or a bi-stable display driver (e.g., an IMOD display driver). Moreover, the display array 30 can be a conventional display array or a bi-stable display array (e.g., a display including an array of IMODs). In some implementations, the driver controller 29 can be integrated with the array driver 22. Such an implementation is common in highly integrated systems such as cellular phones, watches and other small-area displays.

In some implementations, the input device 48 can be configured to allow, e.g., a user to control the operation of the display device 40. The input device 48 can include a keypad, such as a QWERTY keyboard or a telephone keypad, a button, a switch, a rocker, a touch-sensitive screen, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices as are well known in the art. For example, the power supply 50 can be a rechargeable battery, such as a nickel-cadmium battery or a lithium-ion battery. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the disclosure is not intended to be limited to the implementations shown herein, but is to be accorded the widest scope consistent with the claims, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An illumination system, comprising:
a light guide having a frosted light input surface; and
a light source configured to direct light into the frosted light input surface.

2. The illumination system of claim 1, wherein the frosted light input surface has a surface roughness Ra of about 0.1-5 μm.

3. The illumination system of claim 2, wherein the surface roughness Ra is about 0.7-2 μm.

4. The illumination system of claim 2, wherein the frosted light input surface is on an edge of the light guide, wherein peaks and valleys of material on the frosted light input surface define striations extending along a short dimension of the edge.

5. The illumination system of claim 4, wherein the striations are non-uniform and irregularly spaced apart.

6. The illumination system of claim 1, wherein the light guide includes a plurality of light turning features configured to eject light propagating within the light guide out of a major surface of the light guide.

7. The illumination system of claim 6, further comprising a display having a major surface facing the major surface of the light guide, wherein the light turning features are configured to eject light towards the major surface of the light guide.

8. The illumination system of claim 7, wherein the light guide forms part of a front light.

9. The illumination system of claim 7, wherein the display is a reflective display including an array of inteferometric modulators.

10. The illumination system of claim 7, further comprising:
a processor that is configured to communicate with the display, the processor being configured to process image data; and
a memory device that is configured to communicate with the processor.

11. The illumination system of claim 10, further comprising:
a driver circuit configured to send at least one signal to the display.

12. The illumination system of claim 11, further comprising:
a controller configured to send at least a portion of the image data to the driver circuit.

13. The illumination system of claim 10, further comprising:
an image source module configured to send the image data to the processor.

14. The illumination system of claim 13, wherein the image source module includes at least one of a receiver, transceiver, and transmitter.

15. The illumination system of claim 10, further comprising:
an input device configured to receive input data and to communicate the input data to the processor.

16. A method for manufacturing an illumination system, comprising:
providing a light guide having a frosted light input surface; and
providing a light source attached to the light guide and configured to direct light into the frosted light input surface.

17. The method of claim 16, wherein providing the frosted light input surface includes roughening a surface of the light guide.

18. The method of claim 17, wherein roughening the surface includes grinding the surface.

19. The method of claim 17, wherein roughening the surface includes roughening an edge of the light guide.

20. The method of claim 19, wherein roughening the edge includes moving abrasive agents against the edge in a direction substantially along a short dimension of the edge.

21. An illumination system, comprising:
a light guide having a light input surface;
a diffuser coupled to the light input surface; and
a light source configured to direct light into the light guide through the diffuser.

22. The illumination system of claim 21, wherein the diffuser is attached to an edge of the light guide.

23. The illumination system of claim 22, wherein the diffuser is a layer of material adhered to the light input surface.

24. The illumination system of claim 21, wherein the diffuser has a frosted light input surface configured to pass light to the light input surface of the light guide.

25. The illumination system of claim 24, wherein the frosted light input surface has a surface roughness Ra of about 0.1-5 μm.

26. The illumination system of claim 21, wherein embedded structures configured to diffuse light are distributed within the diffuser.

27. The illumination system of claim 21, wherein the light source is embedded in a cavity in the diffuser.

28. The illumination system of claim 27, wherein the diffuser has a haze number of about 65-85.

29. The illumination system of claim 21, further comprising a display, wherein the light guide includes a plurality of light turning features configured to direct light out of the light guide towards the display.

30. The illumination system of claim 29, wherein the display includes an array of inteferometric modulators for display elements.

31. A method for manufacturing an illumination system, comprising:
providing a light guide having a light input surface;
providing a diffuser coupled to the light input surface; and
providing a light source attached to the light guide and configured to direct light into the light guide through the diffuser.

32. The method of claim 31, wherein providing the diffuser includes depositing an optically diffusive coating on the light input surface.

33. The method of claim 31, wherein providing the diffuser includes adhering the diffuser to the light input surface.

34. The method of claim 33, wherein providing the diffuser includes providing the light input surface with a frosted texture.

35. The method of claim 34, wherein providing the light input surface with the frosted texture includes roughening the surface to form the frosted light input surface.

36. The method of claim 35, wherein roughening the surface includes moving abrasive agents against the edge in a direction substantially along a short dimension of the light input surface.

37. An illumination system, comprising:
a light guide having a light input interface;
a light source configured to inject light into the light guide via the light input interface; and
a means for diffusing incoming light at the light input interface.

38. The illumination system of claim 37, wherein the light source is a light emitting diode.

39. The illumination system of claim 37, wherein the light input interface is an edge of the light guide.

40. The illumination system of claim 37, wherein the means for diffusing light is a frosted surface of the light input interface.

41. The illumination system of claim 40, wherein the frosted light input surface has a surface roughness Ra of about 0.1-5 μm.

42. The illumination system of claim 41, wherein the frosted light input surface is on an edge of the light guide, wherein peaks and valleys of material on the frosted light input surface define striations extending along a short dimension of the edge.

43. The illumination system of claim 37, wherein the means for diffusing light is a coating applied to the light input edge or an optically diffusive structure attached to the light input edge.

44. The illumination system of claim 43, wherein the optically diffusive structure has a frosted light input surface disposed between the light source and the light input edge.

45. The illumination system of claim 43, wherein the optically diffusive structure has a plurality of embedded particles for diffusing light.
